(19) United States
(12) Patent Application Publication
(10) Pub. No.: US 2024/0061307 A1
(43) Pub. Date: Feb. 22, 2024

(54) METHODS AND SYSTEMS OF HYPERSPECTRAL IMAGING SYSTEMS EMPLOYING FABRY-PÉROT (FP) FILTER ARRAYS

(71) Applicants: EIJI STEVEN YAFUSO, carlsbad, CA (US); ANNIE VARGHESE, Bangalore (IN)

(72) Inventors: EIJI STEVEN YAFUSO, carlsbad, CA (US); ANNIE VARGHESE, Bangalore (IN)

(21) Appl. No.: 17/888,478

(22) Filed: Aug. 16, 2022

(51) Int. Cl. G02F 1/21; H01L 41/083; H01L 41/09; H01L 41/187

(52) U.S. Cl. CPC G02F 1/213; H01L 41/083; H01L 41/094; H01L 41/1875

(57) ABSTRACT

In one aspect, an active hyperspectral filter array includes a polished wafer comprising a d33 material, wherein the d33 piezoelectric material is configured to display a piezoelectric effect along a same axis of a directed light used to obtain a controlled modulation; wherein the polished wafer comprises: a front electrode on a front surface of the polished wafer, a back electrode on a back surface of the polished wafer, wherein the front electrode and the back electrode are configured such that an optical path length is variable by application of an appropriate electric field.

### BACKGROUND

Standard imaging focal plane arrays (FPA) are necessarily sampling devices in two linear dimensions. Thus conventional imaging systems incorporating hyperspectral acquisition must sacrifice a degree of freedom to accommodate addition of the spectral variable. Once sacrificed, there remains need for an additional apparatus for controlled discrimination of the newly added variable. This latter apparatus is often an imaging spectrometer, which accepts spatial input along a slit input, and then provides spatio-spectral output, with the spatial information along the axis of the slit and spectral data in the orthogonal direction. In remote sensing applications, the slit-spectrometer approach has a major drawback of significant loss of aperture efficiency. That is to say that light gathered at the input objective is mostly lost due to the spatial filtering at the slit plane.

Additionally, spectrally discriminating imaging systems utilize filters or spectrometers to separate and independently assess spectral information. Filters limit light throughput to a specifically predetermined range of wavelength. Spectrometers in their varied forms separate input radiation according to wavelength by refractive or diffractive means. Noted is that spectral discrimination mandates that an imaging instrument possess acquisition in 3 dimensions: 2 spatial, and 1 spectral. The current approach uses the piezoelectric effect in order to form a variable and/or modulated Fabry-Pérot etalon filter. The piezoelectric effect is a well-known phenomenon in which an applied electric field and resulting material polarization, is coupled with a mechanical strain, and resulting elastic deformation. Please refer to the Background figure (See FIG. 8) as an example schematic of a d33 piezoelectric effect.

### SUMMARY OF THE INVENTION

In one aspect, an active hyperspectral filter array includes a polished wafer comprising a d33 material, wherein the d33 piezoelectric material is configured to display a piezoelectric effect along a same axis of a directed light used to obtain a controlled modulation; wherein the polished wafer comprises: a front electrode on a front surface of the polished wafer, a back electrode on a back surface of the polished wafer, wherein the front electrode and the back electrode are configured such that an optical path length is variable by application of an appropriate electric field.

In another aspect, an active hyperspectral filter array includes a d31 Piezoelectric wafer configured such that an applied electric potential causes a piezoelectric effect along an axis perpendicular to the applied electric potential; wherein the d31 Piezoelectric wafer comprises: a front electrode on a front surface of the d31 Piezoelectric wafer, and a back electrode on a back surface of the d31 Piezoelectric wafer; wherein the d31 Piezoelectric wafer comprises a modulator construction with multiple wafers of a d31 material that are polished to a thickness that separates a specified wavelength channels, where the multiple wafers of a d31 material are stacked with a plurality of adjoining electrodes to form a stratified block that alternates between an electrode and a d31 material, and wherein the axis of the piezoelectric effect comprises an optical throughput axis.

In yet another aspect, an active hyperspectral filter array comprising: a plurality of stacked piezoelectric filters comprising a plurality of stacked similar piezoelectric elements together, wherein each stacked similar piezoelectric element comprises a set of individual elements each with an alternating polarity stacked and field applied in a direction of polarization, wherein each layer of the plurality of stacked piezoelectric filters is made by casting a ceramic or organic slurry to form a tape, and wherein each stacked similar piezoelectric element comprises an optically selective Fabry-Perot etalon.

### BRIEF DESCRIPTION OF THE DRAWINGS

FIG. 1 illustrates an example process for hyperspectral imaging systems and specifically to hyperspectral imaging systems employing Fabry-Pérot (FP) filter arrays, according to some embodiments.

FIG. 2 illustrates an example d33 wafer construction, according to some embodiments.

FIG. 3 illustrates an example d33 modulator construction, according to some embodiments.

FIG. 4 illustrates an example schematic of a d31 piezoelectric Effect, according to some embodiments.

FIG. 5 illustrates an example exemplary construction, according to some embodiments.

FIG. 6 illustrates an example set of microstructural modifications, according to some embodiments.

FIG. 7 illustrates an example of stacked piezoelectric filters, according to some embodiments.

FIG. 8 provides a description of example prior art.

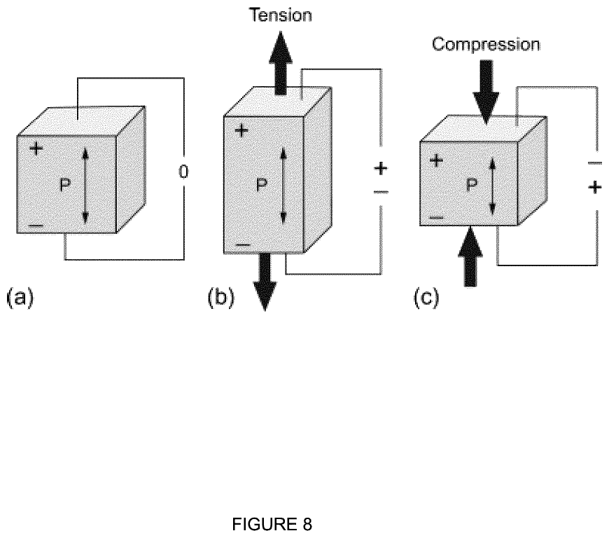

The Figures described above are a representative set and are not exhaustive with respect to embodying the invention.

### DESCRIPTION

Disclosed are a system, method, and article of manufacture of a hyperspectral imaging systems employing Fabry-Pérot (FP) filter arrays. The following description is presented to enable a person of ordinary skill in the art to make and use the various embodiments. Descriptions of specific devices, techniques, and applications are provided only as examples. Various modifications to the examples described herein can be readily apparent to those of ordinary skill in the art, and the general principles defined herein may be applied to other examples and applications without departing from the spirit and scope of the various embodiments.

Reference throughout this specification to “one embodiment,” “an embodiment,” ‘one example,’ or similar language means that a particular feature, structure, or characteristic described in connection with the embodiment is included in at least one embodiment of the present invention. Thus, appearances of the phrases “in one embodiment,” “in an embodiment,” and similar language throughout this specification may, but do not necessarily, all refer to the same embodiment.

Furthermore, the described features, structures, or characteristics of the invention may be combined in any suitable manner in one or more embodiments. In the following description, numerous specific details are provided, such as examples of programming, software modules, user selections, network transactions, database queries, database structures, hardware modules, hardware circuits, hardware chips, etc., to provide a thorough understanding of embodiments of the invention. One skilled in the relevant art can recognize, however, that the invention may be practiced without one or more of the specific details, or with other methods, components, materials, and so forth. In other instances, well-known structures, materials, or operations are not shown or described in detail to avoid obscuring aspects of the invention.

The schematic flow chart diagrams included herein are generally set forth as logical flow chart diagrams. As such, the depicted order and labeled steps are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, and they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

### Definitions

Example definitions for some embodiments are now provided. This definition are provided by way of example and not of limitation.

Bimorph can be a cantilever used for actuation or sensing which consists of two active layers. A bimorph can also include a passive layer between the two active layers.

d31 can be a multi-layer horizontal displacement type (e.g. d31 mode) can be a horizontal displacement type (e.g. d31 mode) piezoelectric element(s) that displace perpendicularly to the lamination direction.

d33 can be a vertical displacement type (d33 mode) Piezoelectric element that displaces along with lamination direction.

Fabry-Pérot (FP) etalon is an optical cavity made from two parallel reflecting surfaces (e.g. thin mirrors). Optical waves can pass through the optical cavity only when they are in resonance with it.

Imaging detectors, also know as Focal Plane Arrays (FPA), are 2-D sampling integrators, Image detector/FPAs can sample a 2-D spatial grid by integration of incident radiation.

Piezoelectric effect is the ability of specified materials to generate an electric charge in response to applied stress.

Unimorph can be a cantilever that consists of one active layer and one inactive layer. In the case where active layer is piezoelectric, deformation in that layer may be induced by the application of an electric field. This deformation may induce a bending displacement in the cantilever. The inactive layer may be fabricated from a non-piezoelectric material.

### Exemplary Methods and Systems

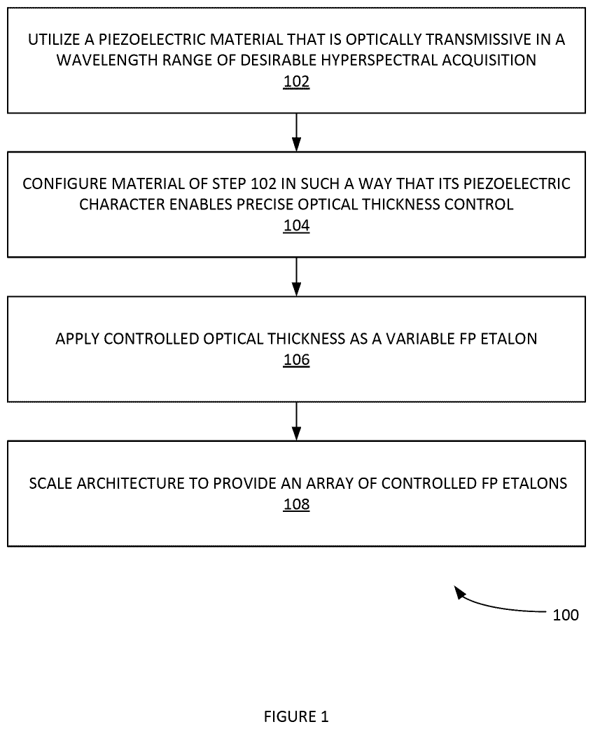

FIG. 1 illustrates an example process 100 for hyperspectral imaging systems and specifically to hyperspectral imaging systems employing Fabry-Pérot (FP) filter arrays, according to some embodiments. In step 102, a current layout approach utilizes a piezoelectric material that is optically transmissive in the wavelength range of desirable hyperspectral acquisition. In step 104, the material is configured in such a way that its piezoelectric character enables precise optical thickness control. In step 106, this controlled optical thickness is then applied as a variable Fabry-Pérot (FP) etalon. In step 108, the architecture is then scaled to provide an array of controlled FP etalons.

It is noted that process 100 improves upon conventional imaging spectrometers as the conventional imaging spectrometers must be integrated with an input imaging system. This can necessarily add bulk, complexity, and alignment sensitivity. By comparison, process 100 uses FP filter arrays to provide greater simplicity, compactness, as well as other significant advantages. Process 100 further takes advantage of large-scale processing to enable development of arrays of active FP filters suitable for hyperspectral imaging systems incorporating large space-bandwidth.

### D33 Piezoelectric Wafer Embodiment

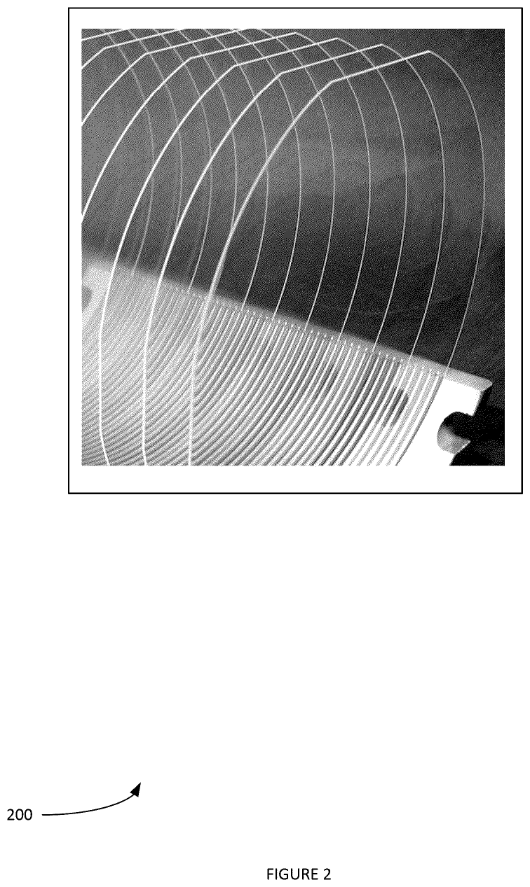

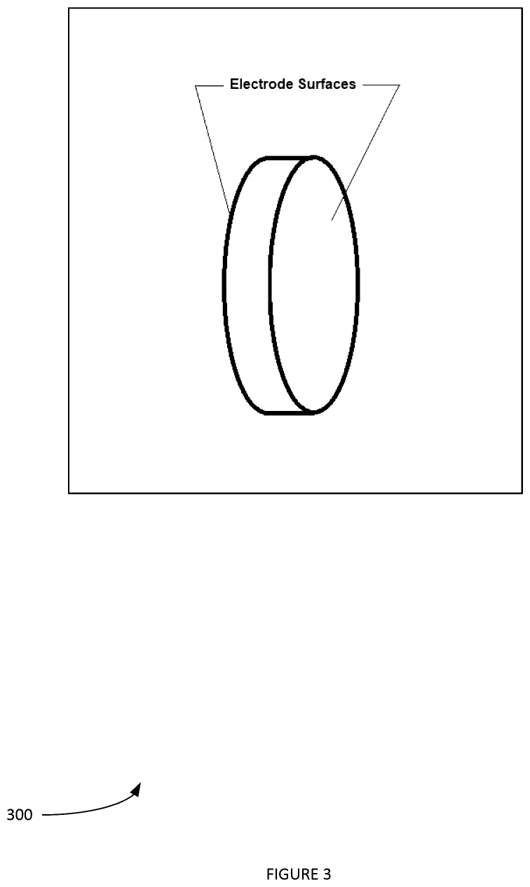

A d33 piezoelectric wafer embodiment is now discussed. An exemplary material can be Monocrystalline Quartz. A d33 piezoelectric material displays the piezoelectric effect along the same axis through which light would be directed in order to obtain controlled modulation. Thus a sample construction would be to use a polished wafer of properly aligned d33 material (e.g. see FIG. 2) and apply electrodes to front and back surfaces (e.g. see FIG. 3), such that the optical path length can be varied by application of an appropriate electric field. The thickness of the polished wafer would be chosen such that, when the optical surfaces are properly coated, the wafer would then form a Fabry-Pérot etalon of desired free spectral range. The etalon can then have high-reflectivity optical coatings applied to both optical surfaces, followed by optically clear electrodes. Once constructed the result would be a highly selective optical filter with a central wavelength tunable by varying the electric potential across the etalon.

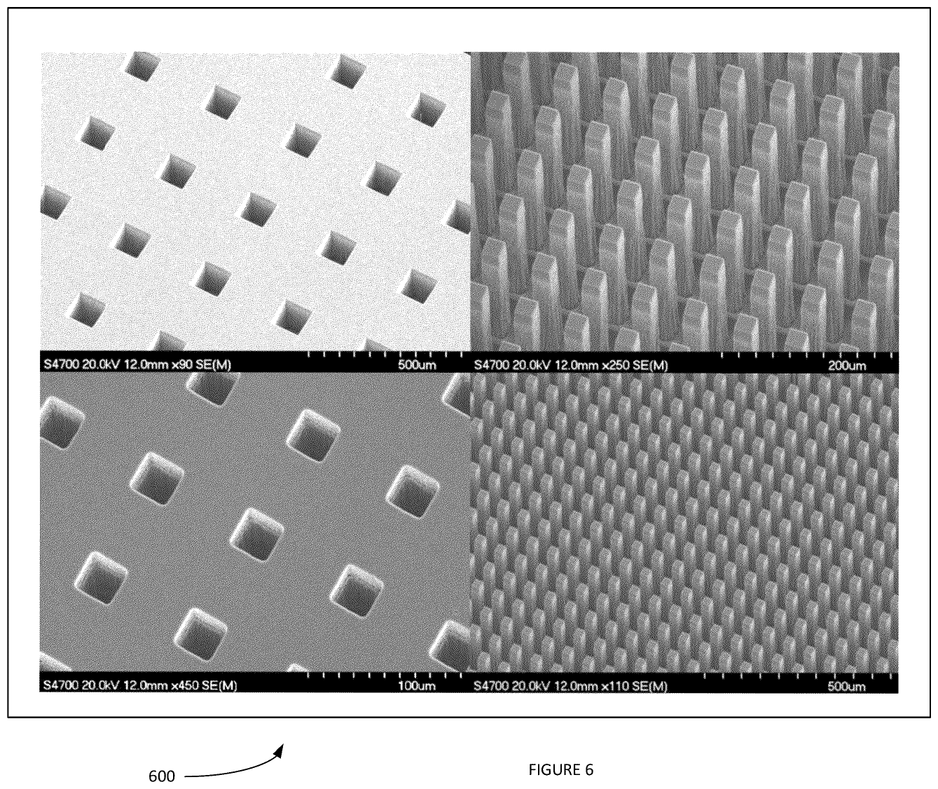

An advantage of the example d33 piezoelectric wafer configuration is convenience. Properly aligned wafers are easily obtainable. They can be polished in parallel and to a desired thickness with conventional optical polishing techniques. Electrodes and optical coatings can be readily applied to both optical surfaces. Additionally, these coatings, and even the microstructure of the optical surfaces (e.g. see FIG. 6) can be spatially tailored using various masking and etching techniques well-established in the electronics and electro-optics industries.

### D31 Piezoelectric Wafer Embodiment

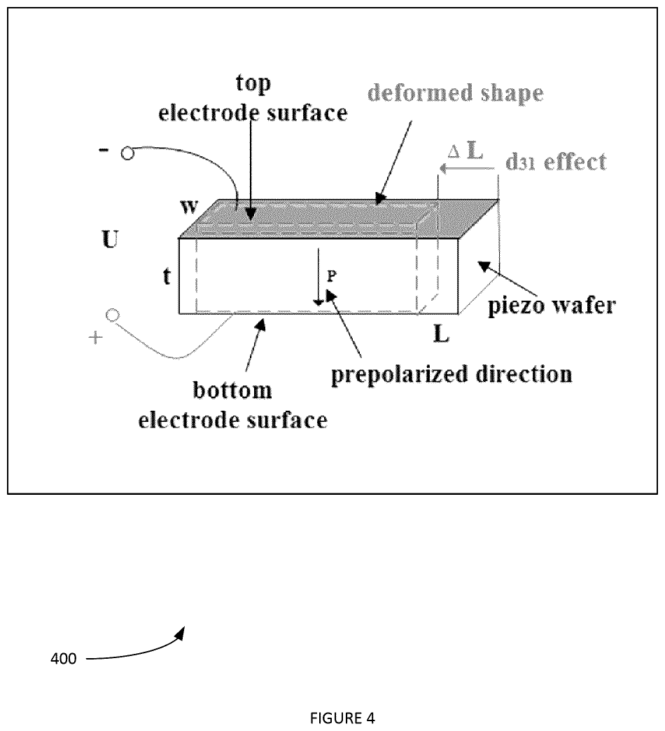

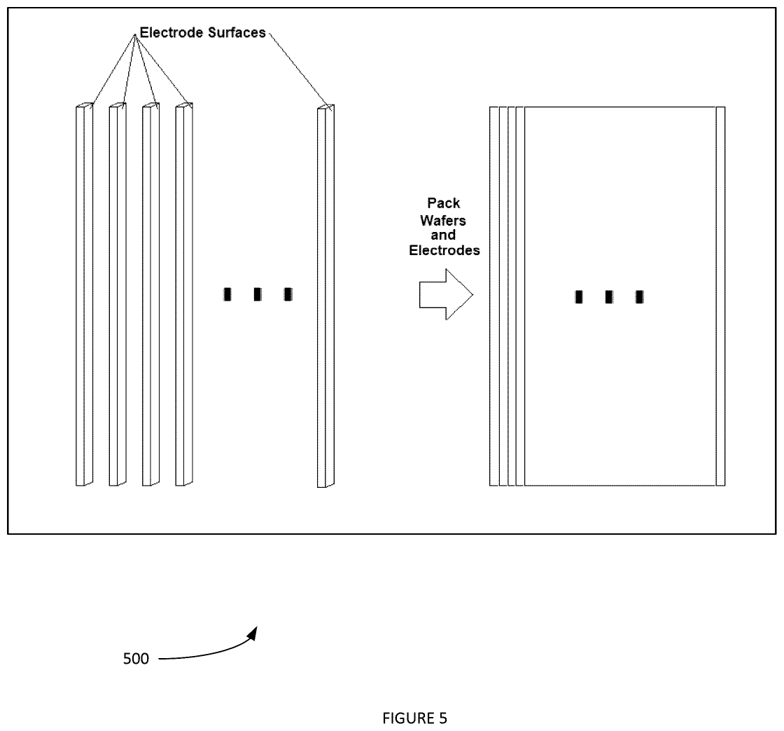

A d31 piezoelectric wafer embodiment is now discussed. This embodiment can be implemented with PMNT. It is noted that with a d31 piezoelectric material, an applied electric potential causes the piezoelectric effect along an axis perpendicular to the applied field as provided in FIG. 4, according to some embodiments. The modulator construction begins with multiple wafers of the d31 material, polished to a thickness which will separate wavelength channels. As with the prior embodiment, electrodes are applied to the polished surfaces (e.g. see FIG. 5). In this embodiment the wafers are then stacked with adjoining electrodes to form a stratified block of alternating electrode and d31 material. The axis of the piezoelectric effect then becomes the optical throughput axis. Thus, this stratified structure can now be cut and polished on the front and back optical throughput faces such that the resulting thickness satisfies the design characteristics of the desired FR etalon. The final step is applying high-reflectivity, dielectric coatings to both optical surfaces.

An advantage of d31 piezoelectric wafer configuration is the absence of need for optically clear electrodes. Another advantage is that, since the etalon electrodes can be separately addressed, the precise FR etalon filter characteristics can be varied for each wavelength channel. Additionally, since two axes are being varied, and by microprocessing local curvatures of the optical surfaces, it is possible to construct a microlenslet array with varying focal length also acting as an array of FR filters.

### Stacked D33 Piezoelectric Wafer

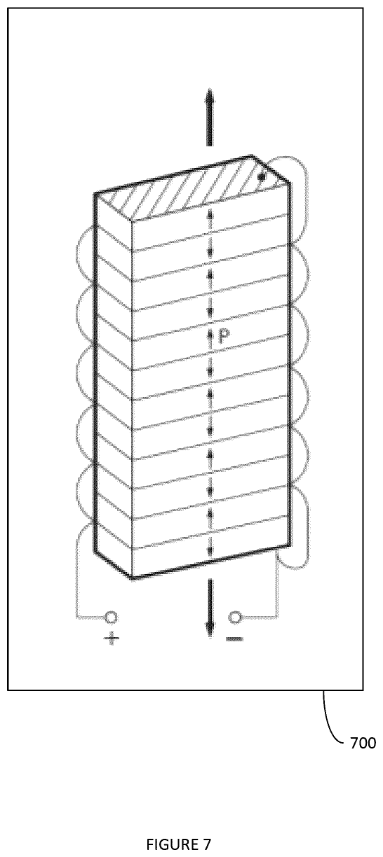

A stacked d33 piezoelectric wafer embodiment is now discussed. FIG. 7 illustrates an example of stacked piezoelectric filters, according to some embodiments. It is noted that the displacement in a single plate piezo-element can be quite small for an applied voltage. The amount of movement yielded is a product of applied voltage and material efficiency figure of merit of the piezo material. The amount of displacement can be multiplied by stacking similar piezo elements together. A sample model encompasses individual elements with alternating polarity stacked and field applied in the direction of polarization. These layers can be made by casting a ceramic or organic slurry to form a tape, dried, and electroded with a thin optically transmissive electrode. Optically selective FP etalon then follows construction as in the d33 piezoelectric wafer embodiment. The use of a piezo stack eliminates the need for secondary position sensor feedback to achieve linear displacement accuracy. The stacked d33 piezoelectric wafer can have a high energy conversion efficiency and quick response speed.

### Unimorphs or Bimorphs Embodiments

Example unimorphs or bimorphs embodiments are now discussed. It is noted that when a d31 crystal is attached to a substrate, it can act as a bending actuator. The piezoelectric element can be designed as an individual layer or a multilayer elements. The electrode can then be placed at the outer surface or at the interface between the plates. A piezoelectric bending actuator can function according to the principle of thermostatic bimetals. A difference being that the controlled stress is not thermal mismatch stress, but rather a thin film stress resulting from the application of an electric field. When a flat piezo contracting actuator is coupled to a substrate, the driving and contraction of the crystal creates a bending moment, which converts the small transverse change in length into a large bending displacement vertical to the contraction. This bending moment can be actively controlled to match the optical f-number. This configuration enables the entire detector plane to be tailored by matching the curvature requirement of the fore-optics.

### Other Example Embodiments

It is noted the various embodiments can be achieved in any configuration which provides a filter or array of filters which can be manipulated by way of the piezoelectric effect.

Filter arrays can also be lenses. FP etalons can take on any form which creates phase resonance between the highly reflective surfaces defining the etalon. Accordingly a micro-lens whose center of curvature coincides with the filter arrays with quasi-continuous wavelength variation across the array filters whose variation is oriented to vary along either of a focal plane array detector's horizontal or vertical axis. Filters whose variation is oriented along an arbitrary axis relative to a focal plane array's horizontal or vertical axes.

### Use Cases

Although not limited to a specific use case the present invention can be used on Earth-observing satellite platforms in which spectrally selective imaging using the current invention is performed in conjunction with imaging focal plane arrays. These arrays can be of various space-bandwidths and are not limited to specific spectral ranges, but rather the current invention can be tailored to work across any spectral range. It is also possible to employ the current invention as a means of achieving real-time adjustment to the precise parameters of spectrum in multispectral or hyperspectral imaging systems.

### CONCLUSION

Although the present embodiments have been described with reference to specific example embodiments, various modifications and changes can be made to these embodiments without departing from the broader spirit and scope of the various embodiments. Accordingly, the specification and drawings are to be regarded in an illustrative rather than a restrictive sense.

What is claimed by United States patent:

1. An active hyperspectral filter array comprising:
a polished wafer comprising a d33 material,
wherein the d33 piezoelectric material is configured to display a piezoelectric effect along a same axis of a directed light used to obtain a controlled modulation;
wherein the polished wafer comprises:
a front electrode on a front surface of the polished wafer,
a back electrode on a back surface of the polished wafer,
wherein the front electrode and the back electrode are configured such that an optical path length is variable by application of an appropriate electric field.

2. The active hyperspectral filter array of claim 1, wherein a thickness of the polished wafer is configured to form a Fabry-Perot etalon of desired free spectral range when one or more optical surfaces of the polished wafer are coated.

3. The active hyperspectral filter array of claim 2, wherein the Fabry-Perot etalon has a high-reflectivity optical coating applied to both optical surfaces, followed by an optically clear electrode.

4. The active hyperspectral filter array of claim 3, wherein the Fabry-Perot etalon comprises a selective optical filter with a central wavelength tunable by varying an electric potential across the Fabry-Perot etalon.

5. The active hyperspectral filter array of claim 4, wherein the polished wafer comprises a Monocrystalline Quartz.

6. An active hyperspectral filter array comprising:
a d31 Piezoelectric wafer configured such that an applied electric potential causes a piezoelectric effect along an axis perpendicular to the applied electric potential;
wherein the d31 Piezoelectric wafer comprises:
a front electrode on a front surface of the d31 Piezoelectric wafer, and
a back electrode on a back surface of the d31 Piezoelectric wafer;
wherein the d31 Piezoelectric wafer comprises a modulator construction with multiple wafers of a d31 material that are polished to a thickness that separates a specified wavelength channels, where the multiple wafers of a d31 material are stacked with a plurality of adjoining electrodes to form a stratified block that alternates between an electrode and a d31 material, and
wherein the axis of the piezoelectric effect comprises an optical throughput axis.

7. The active hyperspectral filter array of claim 6, wherein the d31 Piezoelectric wafer comprises a stratified structure that is cut and polished on a front portion and a back optical throughput face such that a resulting thickness satisfies a design characteristics of a desired Fabry-Perot etalon.

8. The active hyperspectral filter array of claim 7, wherein the d31 Piezoelectric wafer comprises a high-reflectivity, dielectric coating to both optical surfaces.

9. The active hyperspectral filter array of claim 8, wherein the d31 Piezoelectric wafer comprises a PMNT material.

10. The active hyperspectral filter array of claim 6, wherein a d31 crystal is attached to a substrate to act as a piezoelectric bending actuator.

11. The active hyperspectral filter array of claim 6, wherein the piezoelectric bending actuator function according to a principle of thermostatic bimetals.

12. An active hyperspectral filter array comprising:
a plurality of stacked piezoelectric filters comprising a plurality of stacked similar piezoelectric elements together,
wherein each stacked similar piezoelectric element comprises a set of individual elements each with an alternating polarity stacked and field applied in a direction of polarization,
wherein each layer of the plurality of stacked piezoelectric filters is made by casting a ceramic or organic slurry to form a tape, and
wherein each stacked similar piezoelectric element comprises an optically selective Fabry-Perot etalon.

13. The active hyperspectral filter array of claim 12, wherein the tape is dried and electroded with a thin optically transmissive electrode.

14. The active hyperspectral filter array of claim 13, wherein use of a piezoelectric stack eliminates a need for secondary position sensor feedback to achieve a linear displacement accuracy.
